(19) United States
(12) Patent Application Publication
(10) Pub. No.: US 2010/0150190 A1
(43) Pub. Date: Jun. 17, 2010

(54) Laser Wavelength Control

(75) Inventors: Taha Masood, Issaquah, WA (US); Joel D. Hopkins, Sammamish, WA (US)

Correspondence Address: MICROVISION, INC., 6222 185TH AVENUE NE, REDMOND, WA, 98052, US

(73) Assignee: Microvision, Inc., Redmond, WA (US)

(21) Appl. No.: 12/335,161

(22) Filed: Dec. 15, 2008

(51) Int. Cl. H01S 5/06

(52) U.S. Cl. 372/29.023; 372/38.02; 372/38.01

(57) ABSTRACT

The wavelength of light output from a semiconductor laser varies over time as various parameters vary. Current in a phase section of the semiconductor laser is modified to counteract the wavelength variations. The current in the phase section may be modified in response to video data on a pixel-by-pixel basis or longer.

### FIELD

The present invention relates generally to semiconductor lasers, and more specifically to wavelength control in semiconductor lasers.

### BACKGROUND

A laser produces light at a particular wavelength, although the wavelength typically is not perfectly constant. Various mechanisms regarding lasers cause the output light wavelength to change by varying degrees. For example, output light wavelengths may vary as a result of temperature changes.

### BRIEF DESCRIPTION OF THE DRAWINGS

FIG. 1 shows a system to provide fast laser wavelength control;

FIG. 2 shows a semiconductor laser with fast and slow wavelength control;

FIG. 3 shows a semiconductor laser with a second harmonic generator;

FIG. 4 shows an acceptance bandwidth of a second harmonic generator;

FIG. 5 shows a system to provide fast and slow laser wavelength control;

FIG. 6 shows a color laser projection apparatus with laser wavelength control;

FIGS. 7 and 8 show flowcharts in accordance with various embodiments of the present invention; and

FIG. 9 shows a mobile device in accordance with various embodiments of the present invention.

### DESCRIPTION OF EMBODIMENTS

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein in connection with one embodiment may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

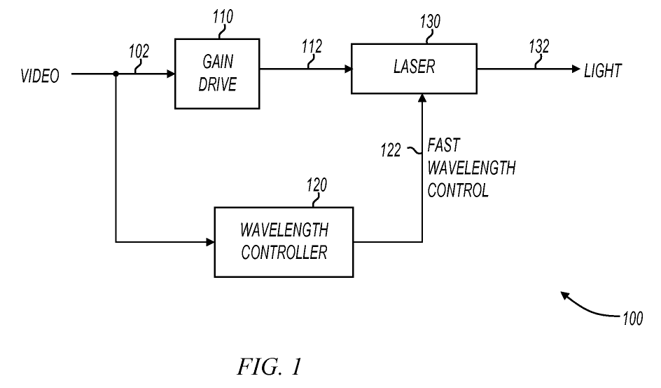

FIG. 1 shows a system to provide fast laser wavelength control in a semiconductor laser. System 100 includes gain drive 110, semiconductor laser 130, and wavelength controller 120. In operation, gain drive 110 receives video data on node 102 and produces a laser drive signal on node 112. In response to the laser drive signal on node 112, semiconductor laser 130 produces light at 132. Laser 130 produces more light for larger amplitude drive signals.

In some embodiments, gain drive 110 may map desired output light intensity to laser drive signals. For example, semiconductor laser 130 may have a nonlinear characteristic, and gain drive 110 may map brightness values for each pixel in the video data to a corresponding laser current drive value. Gain drive 110 may also include current driver circuits to drive semiconductor laser 530 with a drive current.

Semiconductor laser 130 is a laser that responds to multiple control signals. Light is produced in response to the drive signal on node 112, and the wavelength of the produced light is modified as a function of the fast wavelength control signal on node 122. Example semiconductor laser embodiments exhibiting these characteristics are described further below. The various embodiments of the present invention may be used in conjunction with, or may incorporate, any laser light producing device that can quickly modify an output light wavelength in response to a control signal.

Wavelength controller 120 also receives video data on node 102. In response to the video data, wavelength controller 120 modifies a control signal on node 122, and laser 130 quickly modifies the wavelength of the light in response thereto. In some embodiments, wavelength controller 120 filters video data to determine a value for the fast wavelength control signal. For example, wavelength controller 120 may average video data over a time period, and the fast wavelength control signal may be derived from the averaged video data. In other embodiments, wavelength controller 120 modifies the fast wavelength control signal on node 122 at a pixel rate in a scanned image.

Wavelength controller 120 may be implemented in many different ways without departing from the scope of the present invention. For example, in some embodiments, wavelength controller 120 includes a processor that executes software, and in other embodiments, wavelength controller 120 includes, or is part of, an application specific circuits (ASIC).

Semiconductor laser 130 may exhibit a change in output wavelength based on one or more conditions. For example, the temperature of laser 130 may affect the output wavelength. Also for example, the amplitude of the drive signal may affect the output wavelength.

Various embodiments of the present invention provide a fast changing control signal to control the output wavelength based in part on the gain drive signal provided to the laser. For example, in embodiments represented by FIG. 1, the laser gain drive signal is derived from video data, and the fast wavelength control signal is also derived from the same video data. Output wavelength variations caused by the gain drive signal amplitude are compensated as a result.

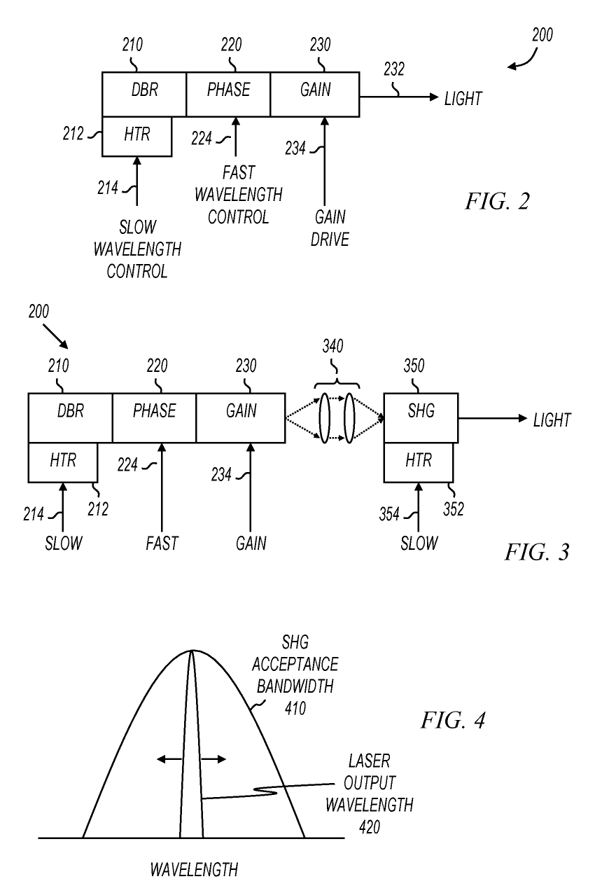

FIG. 2 shows a semiconductor laser with fast and slow wavelength control. Semiconductor laser 200 includes a Distributed Bragg Reflector (DBR) section 210, a phase matching section 220, and a gain section 230. FIG. 2 also shows a heater (HTR) 212 to heat DBR section 210. The DBR section 210 may include, for example, a first order or second order Bragg grating that is positioned outside the active region of the laser cavity. This section provides wavelength selection, as the grating acts as a mirror whose reflection coefficient depends on the wavelength. The gain section 230 of the semiconductor laser 200 provides the major optical gain of the laser and the phase matching section 220 creates an adjustable phase shift between the gain material of the gain section 230 and the reflective material of the DBR section 210. In some embodiments, DBR section 210 may provide wavelength selection using any of a number of suitable alternative configurations that may or may not employ a Bragg grating.

In operation, photons are produced in gain section 230 in response to a gain drive signal on node 234. This corresponds to the drive signal on node 112 driving laser 130 (FIG. 1). Photons emerge from laser 200 as light at 232. The wavelength of the light produced may vary based on a number parameters. For example, temperature variations in DBR section 210 may cause the wavelength to change. Also for example, a bias current in the phase section 220 may also cause the wavelength to change.

DBR heater 212 receives a slow wavelength control signal on node 214 to control heating of DBR section 210. By modifying the slow wavelength control signal, the temperature of DBR section 210 can be changed, and the output light wavelength can also be changed. Modifying the output light wavelength by controlling the temperature of DBR section 210 is a relatively slow process in part because of the thermal time constants involved.

Phase section 220 receives a fast wavelength control signal on node 224 to control the output light wavelength by changing an amount of phase shift provided. Modifying the output light wavelength by changing a bias current in the phase section is a relatively fast process in part because it relies on electro-optic effect and it does not rely on thermal time constants. Accordingly, the output light wavelength may be adjusted using both the slow wavelength control signal on node 214 and the fast wavelength control signal on node 224.

Modulation of the laser to achieve different light intensity output is achieved by driving current in the gain section to produce photons. This drive current may have a heating effect on the gain section, which may in turn cause the output wavelength to change. For example, when the gain current increases, the temperature of the gain section also increases. As a consequence, the cavity modes move towards higher wavelengths. Cumulative heating effects caused by a history of modulation may also cause wavelength changes.

Output light wavelengths may also vary as a result of current induced index suppression in the phase section. The output light wavelength will either increase or decrease depending on which effect (heating or current induced index suppression) is dominant. For example, the wavelength will get longer if heating is dominant, and shorter if current induced index suppression is dominant.

As current is supplied to gain section 230 to modulate laser 200, the output light wavelength shifts based on the phenomena described above. Various embodiments of the present invention compensate for these wavelength shifts by intelligently controlling the slow wavelength control signal and the fast wavelength control signal.

FIG. 3 shows a semiconductor laser with a second harmonic generator (SHG). Semiconductor laser 200 is described above with referent to FIG. 2. Semiconductor laser 200 is optically coupled to second harmonic generator (SHG) 350. Some embodiments include an SHG heater 352 controlled by a slow wavelength control signal on node 354. The light beam emitted by semiconductor laser 200 can be either directly coupled into a waveguide of SHG 350, or can be coupled through collimating and focusing optics or some other type of suitable optical element or optical system. FIG. 3 shows laser 200 optically coupled to SHG 350 through adaptive optics 340, although this is not a limitation of the present invention. Second harmonic generator 350 converts the incident light into higher harmonic waves and outputs light at substantially one half the wavelength of the light emitted by laser 200. This type of configuration is particularly useful in generating shorter wavelength laser beams from longer wavelength semiconductor lasers and can be used, for example, as a visible laser source for laser projection systems.

In some embodiments, an infrared semiconductor laser is used with an SHG to produce green light. For example, a 1064 nm semiconductor laser can be tuned to the spectral center of an SHG crystal, which converts the wavelength to 532 nm (green). However, the wavelength conversion efficiency of an SHG crystal, such as an MgO-doped periodically poled lithium niobate (PPLN), is strongly dependent on the wavelength matching between the semiconductor laser and the SHG device. Accordingly, the conversion efficiency becomes strongly dependent on the ability to match the output light wavelength of the semiconductor laser to the SHG device. The DBR heater 212 accepts a slow wavelength control signal on node 214. The wavelength control effects of heating DBR 210 are described above. The SHG heater 352 also accepts a slow wavelength control signal on node 354. The SHG has a bandwidth associated therewith (see the discussion of acceptance bandwidth below with reference to FIG. 4), and this bandwidth may be modified by heating SHG 352. Various embodiments of the present invention provide relatively slow matching by modifying one or both of the heater control signals on node 214 and 354, and relatively fast matching by modifying the fast waveform control signal on node 224.

Various embodiments that refer to a frequency doubling green laser are further described below. These embodiments refer to an infrared semiconductor laser and an SHG that converts infrared energy to light in the visible spectrum. One skilled in the art will understand that the various embodiments described are not limited to a green laser. The green laser embodiments simply provide a suitable framework to describe the inventive methods, apparatus, and systems.

FIG. 4 shows an acceptance bandwidth of a second harmonic generator. Acceptance bandwidth 410 is shown along with laser output wavelength 420. The term “acceptance bandwidth” is used herein to describe input bandwidth characteristics of an SHG device. The acceptance bandwidth of a PPLN SHG device is often very small: for a typical PPLN SHG wavelength conversion device, the full width half maximum (FWHM) wavelength conversion bandwidth is only in the 0.1 to 0.2 nm range (for a 1 cm long crystal) and mostly depends on the length of the crystal. Mode hopping and uncontrolled large wavelength variations within the laser cavity can cause the output wavelength of a semiconductor laser to move outside of this allowable bandwidth during operation. Once the semiconductor laser wavelength deviates outside the wavelength conversion bandwidth of the PPLN SHG device, the output power of the conversion device at the target wavelength drops.

The output power of the higher harmonic light wave generated in the SHG 350 drops drastically when the output wavelength 420 of the laser 200 deviates from the acceptance bandwidth of the SHG 350. For example, when a semiconductor laser is modulated to produce data, the thermal load may vary. The resulting change in laser temperature and lasing wavelength generates a variation of the efficiency of the SHG 350. In the case of an SHG 350 in the form of a 12 mm-long PPLN device, a temperature change in the semiconductor laser 200 of about 2 degrees C. will typically be enough to take the output wavelength of the laser 200 outside of the 0.16 nm full width half maximum (FWHM) wavelength conversion bandwidth of the SHG 350.

Various embodiments of the present invention address this problem by intelligently modifying the laser wavelength based on measured light output and also based on video signal levels. Various embodiments of the present invention may also tune the acceptance bandwidth of the SHG 350 in order to move the acceptance bandwidth relative to the laser output wavelength. For example, a slow change in acceptance bandwidth may be effected by modifying a control signal to SHG heater 352 (FIG. 3).

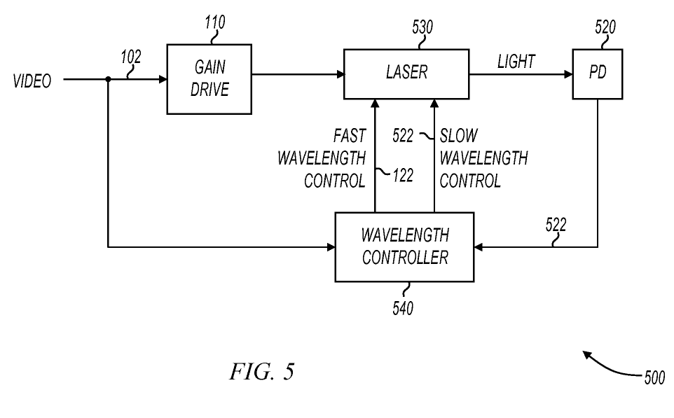

FIG. 5 shows a system to provide fast and slow laser wavelength control. System 500 includes gain drive 110, semiconductor laser 530, photodetector (PD) 520, and wavelength controller 540. System 500 is similar to system 100 (FIG. 1) with the exceptions that wavelength controller 540 is responsive to both video data on node 102 and to a measured light signal on node 522, and that it also modifies the laser wavelength using both fast wavelength control and slow wavelength control.

In some embodiments, laser 530 includes a semiconductor laser such as those shown in FIGS. 2 and 3. In these embodiments, wavelength controller 520 may determine appropriate values for the slow and fast wavelength control signals as a function of observed output light power, and also as a function of video content. For example, the slow wavelength control signal may be updated periodically based on observed longer term output power variations corresponding to laser wavelength shifts in frequency doubling embodiments, and the fast wavelength control signal may be updated periodically based on predicted shorter term wavelength shifts caused by gain drive signal values.

In some embodiments, the slow wavelength control signal on node 522 commands a heater value to a DBR heater, and in other embodiments, the slow wavelength control signal on node 522 commands a heater value to an SHG heater. In still further embodiments, the slow wavelength control signal includes multiple signals to change heater values for both a DBR heater and an SHG heater.

Semiconductor lasers are dynamic, meaning they will “mode hop”. Mode hops result in changes in laser wavelength. Even for a fixed phase section current, a fixed gain section current, and a fixed DBR heating value, the wavelength may still shift because of mode hops. In some embodiments, a random phase section current is provided to cause the output wavelength to intentionally move about relative to the acceptance bandwidth. The DC component of the phase section current may still be changed based on video data, but a superimposed random current component may help to average out dynamic effects.

Controlling the laser wavelength using phase section currents based on video content may by itself reduce the number of mode hops. Mode hops tend to occur more frequently when the DBR heater is modified. Controlling the wavelength using both the DBR heater and the phase section current reduces the amount of DBR heater changes, and therefore reduces the number of mode hops. Reducing DBR heater changes and adding a random component to the phase section current that is determined as a function of video content further reduces the adverse effects of mode hops.

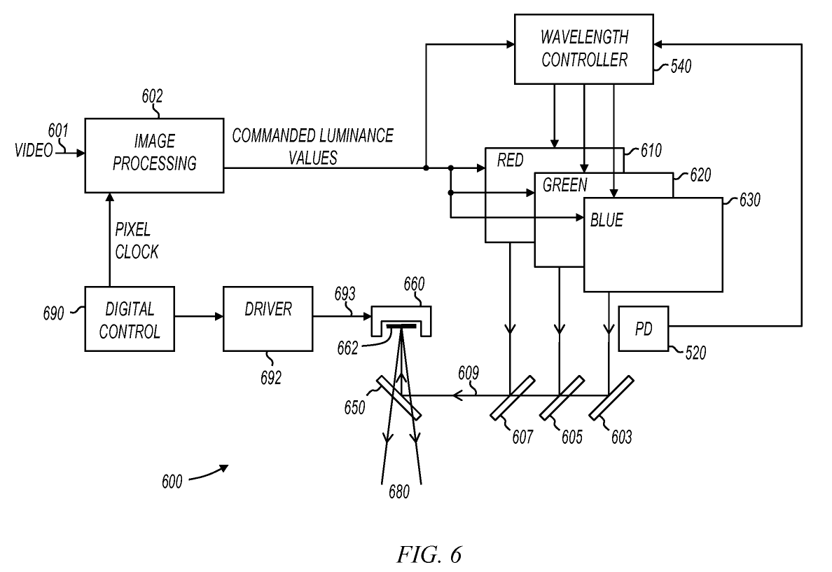

FIG. 6 shows a color laser projection apparatus. System 600 includes image processing component 602, laser light sources 610, 620, and 630. Projection system 600 also includes mirrors 603, 605, and 607, filter/polarizer 650, micro-electronic machine (MEMS) device 660 having mirror 662, MEMS driver 692, digital control component 690, photodetector(s) (PD) 520, and wavelength controller 540.

In operation, image processing component 602 receives video data on node 601, receives a pixel clock from digital control component 690, and produces commanded luminance values to drive the laser light sources when pixels are to be displayed. Image processing component 602 may include any suitable hardware and/or software useful to produce color luminance values from video data. For example, image processing component 602 may include application specific integrated circuits (ASICs), one or more processors, or the like.

Laser light sources 610, 620, and 630 receive commanded luminance values and produce light. Laser light sources 610, 620, and 630 may include any of the semiconductor lasers described herein. For example, green laser light source 620 may include a semiconductor laser and second harmonic generator such as those shown in FIG. 3.

Each light source produces a narrow beam of light which is directed to the MEMS mirror via guiding optics. For example, blue laser light source 630 produces blue light which is reflected off mirror 603 and is passed through mirrors 605 and 607; green laser light source 620 produces green light which is reflected off mirror 605 and is passed through mirror 607; and red laser light source 610 produces red light which is reflected off mirror 607. At 609, the red, green, and blue light are combined. The combined laser light is reflected off filter/polarizer 650 on its way to MEMS mirror 662. The MEMS mirror rotates on two axes in response to electrical stimuli received on node 693 from MEMS driver 692. After reflecting off MEMS mirror 662, the laser light passes through filter/polarizer 650 to create an image at 680.

Wavelength controller 540 can control the wavelength of one or more of laser light sources 610, 620, and 630 as described above. In addition, wavelength controller 540 receives measured light values from PD 520. PD 520 may measure light output from one or more of laser light sources 610, 620, and 630.

In response to commanded luminance values, wavelength controller 540 provides wavelength tuning signals to the various laser light sources. For example, if an upcoming green pixel value calls for a drive current large enough to cause an increase in laser wavelength, then wavelength controller 540 may command green light source 620 to reduce the laser wavelength as described herein. This may be performed for every pixel.

In some embodiments, a DC bias phase section current is determined and applied to the semiconductor laser(s). The term “DC” refers to the static current value over a pixel period. In this manner, video drive values are used to modify the DC bias phase section current to provide the desired wavelength shift. In some embodiments, a random noise component is also added to the phase section current, so that the laser output wavelength will pass through the peak of the SGH acceptance bandwidth (see FIG. 4).

The MEMS based projector is described as an example application, and the various embodiments of the invention are not so limited. For example, the semiconductor lasers and wavelength control apparatus and methods described herein may be used with other optical systems without departing from the scope of the present invention.

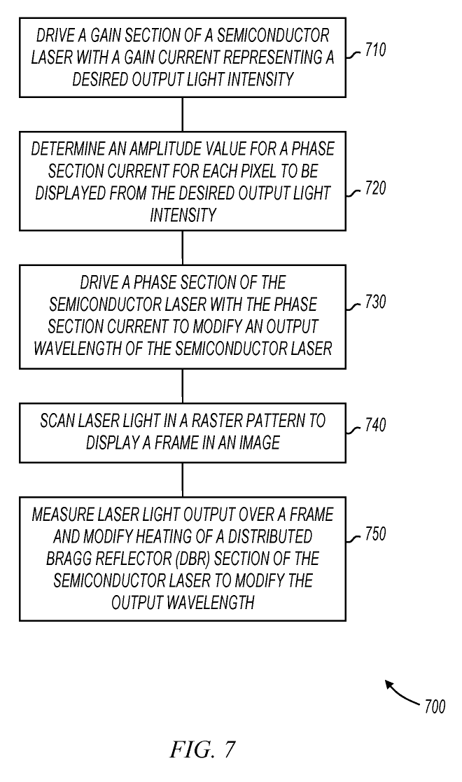

FIG. 7 shows a flowchart in accordance with various embodiments of the present invention. In some embodiments, method 700, or portions thereof, is performed by a semiconductor laser wavelength controller, a mobile projector, or the like, embodiments of which are shown in previous figures. In other embodiments, method 700 is performed by an integrated circuit or an electronic system. Method 700 is not limited by the particular type of apparatus performing the method. The various actions in method 700 may be performed in the order presented, or may be performed in a different order. Further, in some embodiments, some actions listed in FIG. 7 are omitted from method 700.

Method 700 is shown beginning with block 710 in which a gain section of a semiconductor laser is driven with a gain current representing a desired output light intensity. This corresponds to any of the semiconductor lasers described herein being driven with a luminance value derived from video data. For example, as shown in FIG. 6, laser light sources 610, 620, and 630 are driven with luminance data derived from video data.

At 720, an amplitude value for a phase section current for each pixel to be displayed is determined from the desired output light intensity. At 730, a phase section of the semiconductor laser is driven with the phase section current to modify an output wavelength of the semiconductor laser. Driving the phase section with a current derived from a pixel value allows fast modification of output wavelengths to compensate for wavelength shifts that would otherwise occur because of the drive signal corresponding to the pixel value.

At 740, laser light is scanned in a raster pattern to display a frame in an image, and at 750, laser light output over the frame is measured, and heating of a DBR section is modified to modify the output wavelength. Changing the DBR heater value allows for changing the output wavelength more slowly than the changes provided by phase section current changes. The light may be measured with a photodetector, such as PD 520 (FIGS. 5, 6). In some embodiments, an SHG heater value is modified in lieu of, or in addition to, the DBR heater value.

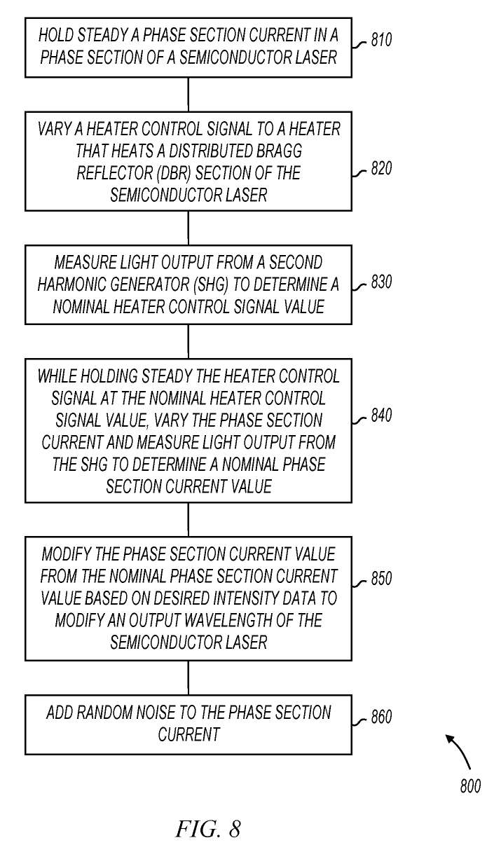

FIG. 8 shows a flowchart in accordance with various embodiments of the present invention. Method 800 represents methods capable of determining a nominal phase section current and a nominal DBR heater value. In some embodiments of method 800, a nominal SHG heater value is also determined. In some embodiments, method 800, or portions thereof, is performed by a semiconductor laser wavelength controller, a mobile projector, or the like, embodiments of which are shown in previous figures. In other embodiments, method 800 is performed by an integrated circuit or an electronic system. Method 800 is not limited by the particular type of apparatus performing the method. The various actions in method 800 may be performed in the order presented, or may be performed in a different order. Further, in some embodiments, some actions listed in FIG. 8 are omitted from method 800.

Method 800 is shown beginning with block 810 in which a phase section current is held steady. For example, a phase section current of 60 mA may be applied. This will have a heating effect, so the wavelength will shift longer. At 820, a heater control signal is varied. This heater control signal may modify heat values applied to a DBR heater, a SHG heater, or both. The remainder of this description refers simply to a DBR heater for simplicity, however it is understood that the various embodiments of the invention are not so limited. Heater control signals may be modified at any frequency, including on a frame-by-frame basis in a video application. After each frame, the DBR heater may be adjusted for this fixed phase section current value while measuring the laser light output (830). In frequency doubling embodiments, it is sufficient to measure light output from the SHG, since light output drops when the laser wavelength moves outside the acceptance bandwidth. A nominal DBR heating value that achieves maximum light output for this fixed phase current (e.g., 60 mA) is found by dithering the DBR heater value and measuring light output over a number of frames.

At 840, the heater control signal is held steady at the nominal heater control signal value. This provides coarse wavelength tuning. The phase section current is varied and light output from the SHG is measured to determine a nominal phase section current value. This may occur at any frequency, including on a frame-by-frame basis in a video application. The nominal phase section current value is a DC bias current that provides the greatest light output for the nominal DBR heating value found at 830.

Once the nominal DBR heater value and nominal phase section current values are known, they can be applied and changed only when necessary. For example, the DBR heater value may be changed on a frame-by-frame basis to provide slow wavelength control, and the phase section current may be changed to provide fast wavelength control.

At 850, the phase section current value is modified from the nominal phase section current value based on desired intensity data to modify an output wavelength of the semiconductor. This corresponds to embodiments represented by FIGS. 1-6, in which the phase section current is modified based on pixel intensity data. At 860, random noise is added to the phase section current. This may be beneficial if the DC value for the phase section current does not place the laser wavelength directly in the center of the SHG acceptance bandwidth or in the case of mode hops. In addition to modifying a DBR heater control value, in some embodiments, an SHG heater control value may modified in order to tune the acceptance bandwidth. The SHG heater control value may be modified instead of, or in addition to, the DBR heater value.

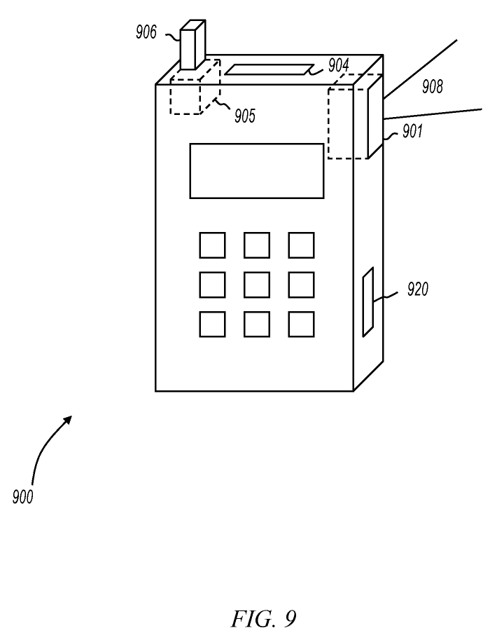

FIG. 9 shows a mobile device in accordance with various embodiments of the present invention. Mobile device 900 may be a hand held projection device with or without communications ability. For example, in some embodiments, mobile device 900 may be a handheld projector with little or no other capabilities. Also for example, in some embodiments, mobile device 900 may be a device usable for communications, including for example, a cellular phone, a smart phone, a personal digital assistant (PDA), a global positioning system (GPS) receiver, or the like. Further, mobile device 900 may be connected to a larger network via a wireless (e.g., WiMax) or cellular connection, or this device can accept data messages or video content via an unregulated spectrum (e.g., WiFi) connection.

Mobile device 900 includes scanning projection device 901 to create an image with light 908. Similar to other embodiments of projection systems described above, mobile device 900 may include a projector with one or more wavelength control apparatus described above.

In some embodiments, mobile device 900 includes antenna 906 and electronic component 905. In some embodiments, electronic component 905 includes a receiver, and in other embodiments, electronic component 1205 includes a transceiver. For example, in global positioning system (GPS) embodiments, electronic component 905 may be a GPS receiver. In these embodiments, the image displayed by scanning projection device 901 may be related to the position of the mobile device. Also for example, electronic component 905 may be a transceiver suitable for two-way communications. In these embodiments, mobile device 900 may be a cellular telephone, a two-way radio, a network interface card (NIC), or the like.

Mobile device 900 also includes memory card slot 904. In some embodiments, a memory card inserted in memory card slot 904 may provide a source for video data to be displayed by scanning projection device 901. Memory card slot 904 may receive any type of solid state memory device, including for example, Multimedia Memory Cards (MMCs), Memory Stick DUOs, secure digital (SD) memory cards, and Smart Media cards. The foregoing list is meant to be exemplary, and not exhaustive.

Mobile device 900 also includes data connector 920. In some embodiments, data connector 920 can be connected to one or more cables to receive analog or digital video data for projection by scanning projection device 901. In other embodiments, data connector 920 may mate directly with a connector on a device that sources video data.

Although the present invention has been described in conjunction with certain embodiments, it is to be understood that modifications and variations may be resorted to without departing from the scope of the invention as those skilled in the art readily understand. Such modifications and variations are considered to be within the scope of the invention and the appended claims.

What is claimed is:

1. A method comprising:
driving a gain section of a semiconductor laser with a gain current representing a desired output light intensity;
determining an amplitude value for a phase section current from the desired output light intensity; and
driving a phase section of the semiconductor laser with the phase section current to modify an output wavelength of the semiconductor laser.

2. The method of claim 1 further comprising adding a noise component to the phase section current.

3. The method of claim 1 wherein determining the amplitude value for the IS phase section current comprises determining the amplitude value for the phase section current for each pixel to be displayed.

4. The method of claim 1 wherein determining the amplitude value for the phase section current comprises averaging desired output light intensity over a plurality of pixels.

5. The method of claim 1 further comprising scanning the light in a raster pattern to display a frame of video data as an image.

6. The method of claim 5 further comprising measuring laser light output over a frame and modifying heating of a Distributed Bragg reflection (DBR) section of the semiconductor laser to modify the output wavelength.

7. The method of claim 6 wherein measuring light comprises measuring the light output from the gain section of the semiconductor laser.

8. The method of claim 6 wherein measuring light comprises measuring the light output from a second harmonic generation device.

9. The method of claim 5 further comprising measuring laser light output over a frame and modifying heating of a second harmonic generation device to modify the output wavelength.

10. A method comprising:
holding steady a phase section current in a phase section of a semiconductor laser;
varying a heater control signal to a heater that heats a Distributed Bragg Reflector (DBR) section of the semiconductor laser;
measuring light output from a Second Harmonic Generator (SHG) to determine a nominal heater control signal value;
while holding steady the heater control signal at the nominal heater control signal value, varying the phase section current and measuring light output from the SHG to determine a nominal phase section current value; and
modifying the phase section current from the nominal phase section current value based on desired intensity data to modify an output wavelength of the semiconductor laser.

11. The method of claim 10 further comprising adding random noise to the phase section current.

12. The method of claim 10 wherein modifying the phase section current comprises modifying the phase section current value at a pixel rate.

13. The method of claim 12 further comprising updating the heater control signal at a frame rate based on measured light output.

14. A projector comprising:
a semiconductor laser including a Distributed Bragg Reflector (DBR) section, a gain section, and a phase section;
an image source coupled to provide pixel luminance data to drive the gain section of the semiconductor laser; and
a wavelength controller coupled to drive a phase section current in the phase section of the semiconductor laser in response to the pixel luminance data to modify an output wavelength of the semiconductor laser.

15. The projector of claim 14 further comprising a second harmonic generator coupled to receive light from the semiconductor laser, the second harmonic generator exhibiting an acceptance bandwidth, and wherein the output wavelength of the semiconductor laser is modified to be in the acceptance bandwidth.

16. The projector of claim 15 further comprising a second harmonic generator heater to heat the second harmonic generator in response to a control signal from the wavelength controller.

17. The projector of claim 15 further comprising a photodetector to detect light output from the second harmonic generator.

18. The projector of claim 17 further comprising a DBR heater to heat the DBR section in response to a control signal from the wavelength controller.

19. The projector of claim 18 wherein the wavelength controller is programmed to update the phase section current at a pixel rate, and to update the control signal to the DBR heater at a frame rate.

20. The projector of claim 15 wherein the acceptance bandwidth of the second harmonic generated is centered at substantially 1064.

21. The projector of claim 14 further comprising a scanning mirror to scan laser light in a raster pattern.

22. A mobile device comprising:
a communications transceiver; and
a laser projector including a semiconductor laser and control system that update a phase section current in a phase section of the semiconductor laser at a pixel rate to modify an output wavelength in response to video data.

23. The mobile device of claim 22 wherein the semiconductor laser includes a Second Harmonic Generator (SHG) having an acceptance bandwidth, and the output wavelength is modified to be in the acceptance bandwidth.

24. The mobile device of claim 22 further comprising a heater to heat a Distributed Bragg Reflector (DBR) section of the semiconductor laser, the control system being coupled to modify a control signal to the heater at a frame rate.
